(19) United States
(12) Patent Application Publication
(10) Pub. No.: US 2025/0218844 A1
(43) Pub. Date: Jul. 3, 2025

(54) SUBSTRATE HOLDING UNIT AND SUBSTRATE PROCESSING APPARATUS

(71) Applicant: Samsung Electronics Co., Ltd., Suwon-si (KR)

(72) Inventors: Iksu Byun, Suwon-si (KR); Junrae Kim, Suwon-si (KR)

(21) Appl. No.: 18/742,533

(22) Filed: Jun. 13, 2024

(30) Foreign Application Priority Data
Dec. 28, 2023 (KR) 10-2023-0194192

(51) Int. Cl. H01L 21/683

(52) U.S. Cl. CPC H01L 21/6833

(57) ABSTRACT

According to an example embodiment of the present disclosure, provided is a substrate holding unit including: a core body having a first surface for supporting a substrate and a second surface opposite to the first surface; an electrode layer disposed on the first surface and the second surface of the core body; and a ceramic insulating layer covering the electrode layer and disposed on the first surface and the second surface of the core body, wherein a first surface of the ceramic insulating layer on the first surface of the core body includes a cubic crystal structure in at least a portion thereof, and includes a hexagonal crystal structure in at least another portion thereof.

### CROSS-REFERENCE TO RELATED APPLICATION(S)

This application claims benefit of priority under 35 U.S.C. § 119 to Korean Patent Application No. 10-2023-0194192, filed on Dec. 28, 2023, in the Korean Intellectual Property Office, the disclosure of which is incorporated herein by reference in its entirety.

### BACKGROUND

The present disclosure relates to a substrate holding unit and a substrate processing apparatus.

A semiconductor device manufacturing process includes various deposition processes such as an etching process for semiconductor wafers and chemical vapor deposition (CVD). A substrate processing apparatus for such a process may include, for example, a CVD apparatus, a deposition apparatus such as a sputtering apparatus, and an etching apparatus such as a plasma etching apparatus.

Such a substrate processing apparatus may include a heating device for heating a semiconductor wafer at a high temperature, and in some substrate processing apparatus, the heating device may be used in combination with a substrate holding unit (e.g., a susceptor).

### SUMMARY

An aspect of the present disclosure is to provide a substrate holding unit combined with an improved heating unit, which may minimize particles disposed in an upper portion thereof during a substrate treatment by compensating for a thermal expansion coefficient.

An aspect of the present disclosure is to provide a substrate processing apparatus having a substrate holding unit which may match signs of a thermal expansion coefficient with a substrate.

According to an aspect of the present disclosure, provided is a substrate holding unit including: a core body having a first surface configured to support a substrate and a second surface opposite to the first surface; an electrode layer disposed on the first and second surfaces of the core body; and a ceramic insulating layer covering the electrode layer and disposed on the first surface and the second surface of the core body, wherein a first surface of the ceramic insulating layer on the first surface of the core body includes a cubic crystal structure in at least a portion thereof, and includes a hexagonal crystal structure in at least another portion thereof.

According to another aspect of the present disclosure, provided is a substrate holding unit including: a core body having a first surface configured to support a substrate and a second surface, disposed opposite to the first surface; an electrode layer disposed on the core body and including pyrolytic graphite providing heat to the substrate; and a ceramic insulating layer covering the electrode layer and disposed on the first surface and the second surface of the core body, and including pyrolytic boron nitride, wherein a first surface of the ceramic insulating layer on the first surface and the second surface of the core body includes a cubic crystal structure in at least a portion thereof, and includes a hexagonal crystal structure in at least another portion thereof, and an area of the cubic crystal structure is 0.1 to 0.2 times an area of the hexagonal crystal structure.

According to another aspect of the present disclosure, provided is a substrate processing apparatus including: a process chamber providing an internal space for processing a substrate; a holding unit disposed in the internal space and configured to support the substrate; and a gas supply unit supplying process gas to the internal space, wherein the holding unit includes: a core body having a first surface for holding the substrate and a second surface, disposed opposite to the first surface; an electrode layer disposed on the first surface and the second surface of the core body; and a ceramic insulating layer covering the electrode layer and disposed on the first surface and the second surface of the core body; wherein a first surface of the ceramic insulating layer on the first surface of the core body includes a cubic crystal structure in at least a portion thereof, and a hexagonal crystal structure in at least another portion thereof.

In some embodiments, a sign of a thermal expansion coefficient of a silicon substrate, which is an object disposed in an upper portion thereof, may be matched with a sign of a thermal expansion coefficient of an outermost surface of a substrate holding unit, expansion directions thereof may be matched to maximize cracks at an outermost surface of the substrate holding unit. Accordingly, the generation of particles due to the cracks may be minimized, thus extending a lifespan. Additionally, for this purpose, crystal rearrangement may be performed to have a partial cubic structure on an outermost surface thereof, thereby increasing stiffness and minimizing abrasion. Furthermore, by limiting an area of the cubic structure, scratches may be minimized on a placed substrate.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a substrate processing apparatus according to an example embodiment of the present disclosure;

FIG. 2 is a plan view illustrating a substrate holding unit (or a substrate heating unit) applicable to the substrate processing apparatus illustrated in FIG. 1;

FIG. 3 is a cross-sectional view illustrating a substrate holding unit applicable to the substrate processing apparatus illustrated in FIG. 2;

FIG. 4 is a top view illustrating an outermost crystal structure of the substrate holding unit of FIG. 3;

FIGS. 5 and 6A-6D illustrate graphs and SEM images respectively illustrating crystallization according to the temperature in pyrolytic boron nitride forming an outermost surface of the substrate holding unit;

FIG. 7 illustrates an expansion direction of a substrate and a substrate holding unit according to crystallization;

FIGS. 8 and 9 are top views respectively illustrating a substrate holding unit according to various example embodiments of the present disclosure; and

FIGS. 10A to 10E are cross-sectional views illustrating a method of manufacturing a substrate holding unit according to an example embodiment of the present disclosure.

### DETAILED DESCRIPTION

Hereinafter, example embodiments of the present disclosure will be described with reference to the accompanying drawings. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

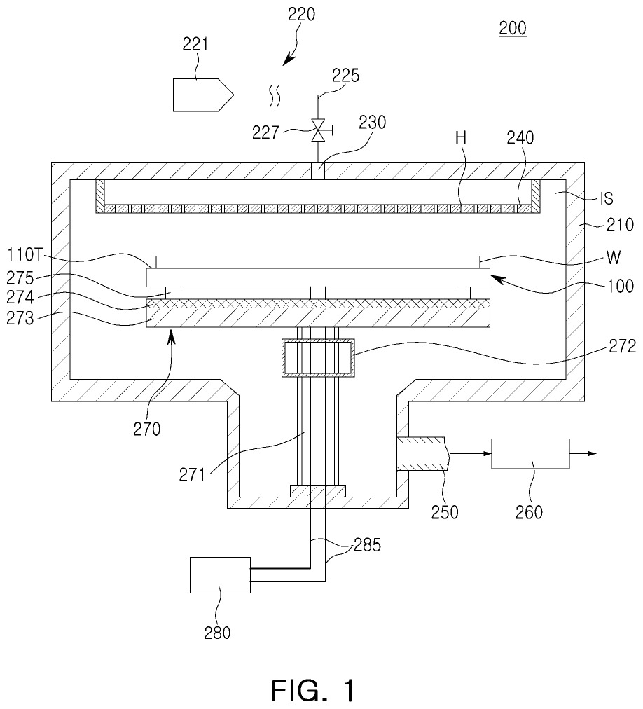

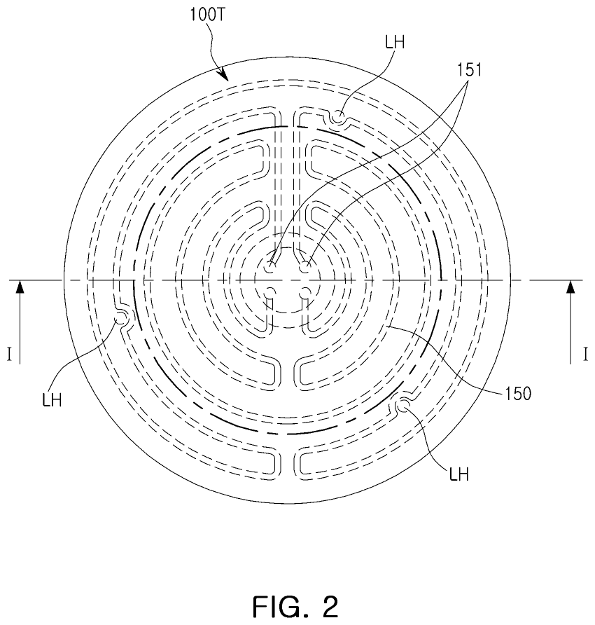

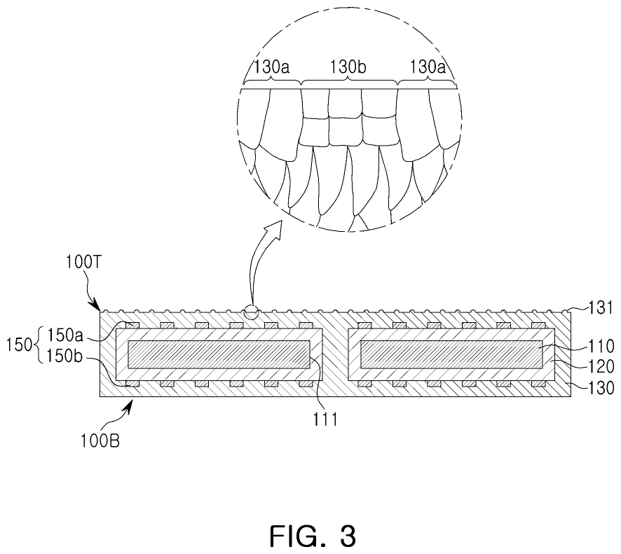

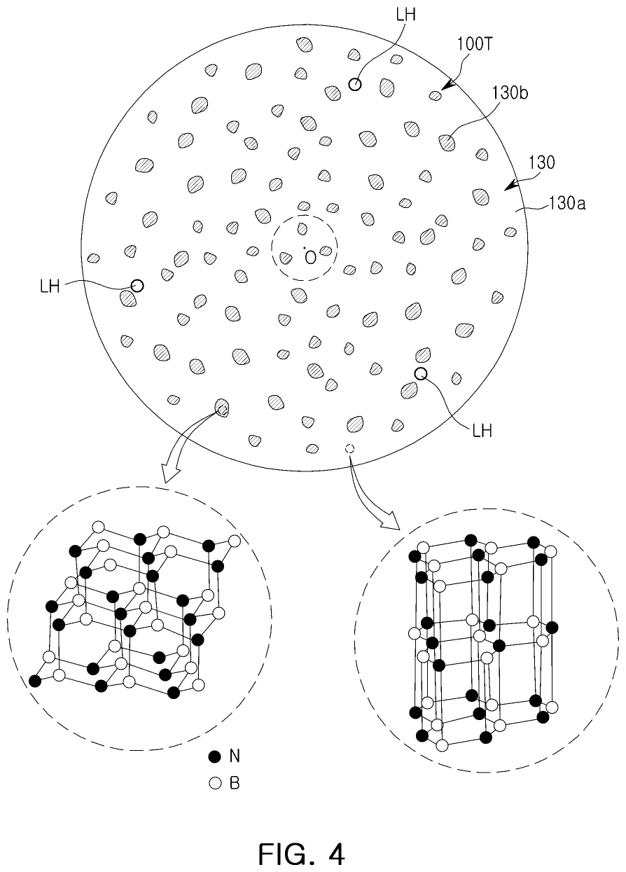

FIG. 1 is a schematic cross-sectional view of a substrate processing apparatus according to an example embodiment of the present disclosure. FIG. 2 is a plan view illustrating a substrate holding unit (or a substrate heating unit) applicable to the substrate processing apparatus illustrated in FIG. 1. FIG. 3 is a cross-sectional view illustrating a substrate holding unit applicable to the substrate processing apparatus illustrated in FIG. 2. FIG. 4 is a top view illustrating an outermost crystal structure of the substrate holding unit of FIG. 3.

Referring to FIG. 1, a substrate processing apparatus 200 according to an example embodiment of the present disclosure may include a process chamber 210 having an internal space IS for processing a substrate W, a substrate holding unit 100 disposed in the internal space IS, and a gas supply unit 220 for supplying gas to the internal space IS.

The substrate processing apparatus 200 according to this example embodiment is illustrated as a plasma enhanced chemical vapor deposition (PECVD) apparatus for depositing a desired film on the substrate W disposed on the substrate holding unit 100 using plasma, but the substrate processing apparatus 200 according to an example embodiment of the present disclosure is not limited thereto, and may be implemented as various other devices for performing a process required to manufacture a semiconductor in a state in which the substrate W is heated at a high temperature.

The process chamber 210 has an internal space IS for performing a process, and one side (e.g., an upper end) of the process chamber 210 may be provided with a gas inlet port 230 for introducing gas and another side (e.g., a lower end) of the process chamber 210 may be provided with an exhaust port 250 for exhausting reaction by-products and residual gas generated in a process. The exhaust port 250 may be connected to a vacuum pump 260. The vacuum pump 260 may create a vacuum to draw out the reaction by-products and residual gas generated in a process from the process chamber 210 through the exhaust port 250.

Referring to FIG. 1, the gas supply unit 220 supplies process gas to the internal space IS through the gas inlet port 230. The gas supply unit 220 may include a gas storage portion 221, a gas supply line 225 and a valve 227. The gas supply line 225 may connect the gas storage portion 221 to the gas inlet port 230, and the process gas stored in the gas storage portion 221 may be supplied through the gas supply line 225 and the gas inlet port 230 to the internal space IS. The valve 227 may be installed in the gas supply line 225 and may open and close a gas supply passage or adjust a flow rate of the process gas supplied to the internal space IS.

The process gas supplied through the gas inlet port 230 may be injected onto the substrate W through a shower head 240. The shower head 240 has injection holes H for injecting gas, and may uniformly inject the reaction gas onto the substrate W through the injection holes H. The shower head 240 may be disposed in an upper side of the internal space IS of the process chamber 210 to face the substrate holding unit 100. The shower head 240 may be provided between the gas inlet port 230 and the substrate holding unit 100. The shower head 240 may have a diameter larger than a diameter of the substrate holding unit 100.

The substrate processing apparatus 200 may include a support 271 extending upwardly from a bottom of the process chamber 210, and a plate unit 270 connected to the support 271 to support the substrate holding unit 100. The substrate holding unit 100 may be fastened to the plate unit 270 in an attachable or detachable state. For example, the substrate holding unit 100 may be fastened to the plate unit 270 may be attached to and/or detached from the plate unit 270.

The plate unit 270 is a cooling unit, and may include a heat shielding layer 274 on an upper surface of the cooling plate 273, and may block heat generated from the substrate holding unit 100 from being transferred to the chamber 210. Accordingly, the heat shielding layer 274 may include a material having significantly low thermal conductivity. The plate unit 270 may further include an angle control unit 272 such that an upper surface thereof is inclined at a predetermined angle with respect to the support 271, and the angle control unit 272 may be a mechanical device that is angle-changeable through a gear or the like between the support 271 and the plate unit 270. A fixing portion 275 for fixing the substrate holding unit 100 may be disposed on an upper surface of the plate unit 270. The substrate holding unit 100 is physically coupled to the plate unit 270 by the fixing portion 275 and thus the substrate holding unit 100 and the plate unit 270 are movable together.

First and second power supply lines 285 connected to the substrate holding unit 100 may be connected to electrodes of the substrate holding unit 100 to be connected to a heating power source 280 disposed outside the process chamber 210 through the plate unit 270 and the support 271. For example, electrodes of the substrate holding unit 100 may be connected to the heating power source 280 via the first and second power supply lines 285. In some example embodiments, the support 271 has a hollow cylinder structure, and the first and second power supply lines 285 may be disposed in an internal space of the support 271.

The substrate holding unit 100 is configured to support the substrate W to be processed in the internal space IS. The substrate holding unit 100 adopted in this example embodiment is coupled to the heating power source 280 heating the substrate W at a desired process temperature in a state in which the substrate W is fixed.

Referring to FIGS. 1 to 3, the substrate holding unit 100 may include a core body 110, a first insulating layer 120 on the core body 110, an electrode layer 150 on the first insulating layer 120, and a second insulating layer 130 covering the electrode layer 150. The second insulating layer 130 may surround the electrode layer 150 and the first insulating layer 120. For example, the second insulating layer 130 may contact the electrode layer 150 and the first insulating layer 120. An upper surface of the second insulating layer 130 may be provided as a substrate stage to form an upper surface 100T of the substrate holding unit 100 on which the substrate W is settled, and a lower surface of the second insulating layer 130 may form a lower surface 100B of the substrate holding unit 100 in contact with the fixing portion 275 of the plate unit 270.

The substrate holding unit 100 is an electrostatic chuck heater, and the core body 110 may include carbon or a carbon composite material, may have a similar thermal expansion rate to that of pyrolytic boron nitride (pBN), and may include a material that is excellent in heat resistance impacts. The carbon material may include graphite or the like.

The core body 110 may have an upper surface facing a direction in which the substrate W is settled, and may have a rear surface facing the plate unit 270 opposite to the upper surface. An exact center of the core body 110 may include an opening hole 111 in which is disposed a connection portion 151 in which an upper electrode 150a connected to the first and second power supply lines 285 extends to a lower surface.

Lower holes LH may be provided in the substrate holding unit 100. The lower holes LH may be provided near an edge of the substrate holding unit 100. As illustrated in FIG. 2, the electrode layer 150 may be formed adjacent to the lower holes LH and may extend around a portion of the perimeter of each of the lower holes LH.

The first insulating layer 120 may be disposed surrounding the core body 110. The first insulating layer 120 may be provided on upper, lower, and side surfaces of the core body 110. For example, the first insulating layer 120 may contact the upper, lower, and side surfaces of the core body 110. The first insulating layer 120 may include pyrolytic boron nitride (pBN) having thermal expansion coefficient in a range similar to that of the core body 110.

Pyrolytic boron nitride (pBN) has electrical resistivity of 10⁸ to 10¹³ Ω·cm. The first insulating layer 120 having such electrical resistivity may allow a weak current to flow to the substrate W, thereby significantly increasing electrostatic force known as the “Johnsen-Rahbek” effect. Pyrolyzed boron nitride (pBN) compactly manufactured by chemical vapor deposition (CVD) has electrical resistivity of about 10¹⁵ Ω·cm at room temperature, but decreases to 10⁸ to 10¹² Ω·cm at temperatures of 800° C. or high, and thus, good electrostatic force may be successfully provided by the “Johnsen-Rahbek” effect. The first insulating layer 120 may cover the core body 110 to have a thickness of 100 μm to 300 μm and may cover an entire inside of the opening hole 111.

The electrode layer 150 including upper electrodes 150a and lower electrodes 150b may be disposed on upper and lower surfaces of the first insulating layer 120, respectively. For example, the upper electrodes 150a may contact the upper surface of the first insulating layer 120, and the lower electrodes 150b may contact the lower surface of the first insulating layer 120. The electrode layer 150 may be formed of pyrolytic graphite (PG). More specifically, a PG electrode layer 150 having a thickness of, for example, about 50 μm may be patterned, such that the upper electrodes 150a may be formed on an upper surface, and the lower electrodes 150b may be formed on a lower surface.

The upper electrodes 150a disposed on the upper surface are chuck electrodes, and may allow a current to flow for fixing a target substrate W, and the lower electrodes 150b disposed on the lower surface are heater electrodes, and may generate heat according to applied voltage and apply the heat to the target substrate W.

The second insulating layer 130 may be disposed to completely cover the electrode layer 150. The second insulating layer 130 may include the same material as the first insulating layer 120, and specifically, may include pyrolytic boron nitride (pBN). As described above, pyrolytic boron nitride (pBN) may significantly increase electrostatic force, and entirely cover the first insulating layer 120 to have a thickness of 100 μm to 300 μm from the electrode layer 150, and may be disposed to fill the opening hole 111. The lower surface of the second insulating layer 130 may be formed to be flat. The upper surface of the second insulating layer 130 may form an upper surface 100T of the substrate holding unit 100 on which the substrate W is placed, in the substrate processing apparatus 200, and the lower surface of the second insulating layer 130 may form a lower surface 100B of the substrate holding unit 100 in contact with the fixing portion 275 of the plate unit 270. Accordingly, a surface of the second insulating layer 130 may be an upper surface 100T of the substrate holding unit 100.

In a case in which the second insulating layer 130 includes pyrolytic boron nitride (pBN), when the second insulating layer 130 is disposed on an outermost surface due to the low stiffness of the pyrolytic boron nitride (pBN), particles may be generated due to friction during the process, which may require the second insulating layer 130 to be periodically replaced. Accordingly, in an example embodiment, the second insulating layer 130 may include crystallized pyrolytic boron nitride (pBN) having an upper surface thereof with amorphous pyrolytic boron nitride (pBN), and may have at least two crystal structures. Specifically, referring to FIG. 3, the upper surface of the second insulating layer 130 may be configured to have a crystallized region in which a first crystal structure 130a and a second crystal structure 130b are mixed. On the upper surface of the second insulating layer 130, the second crystal structure 130b may occupy an area that is 0.1 to 2.7 times that of the first crystal structure 130a. In some embodiments, on the upper surface of the second insulating layer 130, the second crystal structure 130b may occupy an area that is 0.1 to 1 times that of the first crystal structure 130a. In still further embodiments, on the upper surface of the second insulating layer 130, the second crystal structure 130b may occupy an area that is 0.1 to 0.2 times that of the first crystal structure 130a. The second crystal structure 130b may be irregularly dispersed on the upper surface of the second insulating layer 130.

When the second insulating layer 130 includes pyrolytic boron nitride (pBN), after pyrolytic boron nitride (pBN) is deposited by chemical vapor deposition, it may be possible to form a hexagonal crystal structure, which is the first crystal structure 130a in an amorphous state depending on the heat treatment temperature, and it may be possible to form a cubic crystal structure, which is the second crystal structure 130b, at a higher temperature. The pyrolytic boron nitride (pBN) may be formed to include a hexagonal structure, which is the first crystal structure 130a from the amorphous state, in at least a portion thereof by heat treatment after chemical vapor deposition. The second insulating layer 130 of the present disclosure may generate crystallization from the first crystal structure 130a to the second crystal structure 130b or generate crystallization from the amorphous state to the second crystal structure 130b through crystallization at high temperature and high pressure. Accordingly, the upper surface 100T including the second crystal structure 130b may be included to satisfy a desired area ratio.

In a case in which pyrolyzed boron nitride (pBN) is a hexagonal crystal structure as the first crystal structure 130a, when the substrate W is subject to repeated performance of a high-temperature heat treatment while being settled on the upper surface 100T, the substrate W may have thermal expansion coefficient (CTE) of a (−) value contracted in a direction opposite to the substrate W, for example, (−) 2.7(10⁻⁶/K). Considering that the thermal expansion coefficient (CTE) of, the substrate W, i.e., most silicon substrates, is (+) 2.6(10⁻⁶/K), force may be applied externally by tension to the substrate W disposed on the upper surface 100T, whereas in the second insulating layer 130, compression may be applied in an opposite direction to the substrate W, and thus cracks may occur at an interface between the two layers. Meanwhile, boron nitride (pBN) having a cubic crystal structure may have a positive (+) isotropic thermal expansion coefficient (CTE), and tension expanding in the same direction as the substrate W may act. Additionally, pyrolytic boron nitride (pBN) having a cubic crystal structure may have physical properties superior to pyrolytic boron nitride (pBN) of hexagonal crystal structure, and may thus have hardness of up to 170 times and stiffness of up to 10 times, and have a state of very high density. Since the high stiffness of the cubic crystal structure is much higher than that of the silicon substrate W, damage such as scratches may occur on the substrate W, and thus, the high stiffness of the cubic crystal structure may be unsuitable as the substrate holding unit 100. For example, an AlN-based heater has stiffness of 17.7 Gpa, which has a value much larger than 12.5 Gpa, which is the stiffness of the silicon substrate W, such that scratches may occur on the substrate W.

The second insulating layer 130 of an example embodiment of the present disclosure may have a crystal structure in which the hexagonal crystal structure as the first crystal structure 130a and the cubic crystal structure as the second crystal structure 130b are mixed on the upper surface 100T so that the thermal expansion coefficient (CTE) has a positive (+) value that is the same sign as the silicon substrate W and the stiffness has a level lower than that of the silicon substrate W.

As illustrated in FIG. 4, in the second insulating layer 130, a region of the second crystal structure 130b on the upper surface 100T has a predetermined area and may be irregularly dispersed. Additionally, the region of the second crystal structure 130b may have different areas and different shapes.

The region of the second crystal structure 130b is formed sporadically from amorphous pyrolytic boron nitride (pBN) to the second crystal structure 130b through crystallization in the first crystal structure 130a, and when the crystallization is completely performed, regions of the sporadically dispersed second crystal structure 130b are adjacent to each other, and the upper surface has the second crystal structure 130b as a whole. In FIG. 4, the boron B is represented by an empty circle, and the nitride N is represented by a solid black circle.

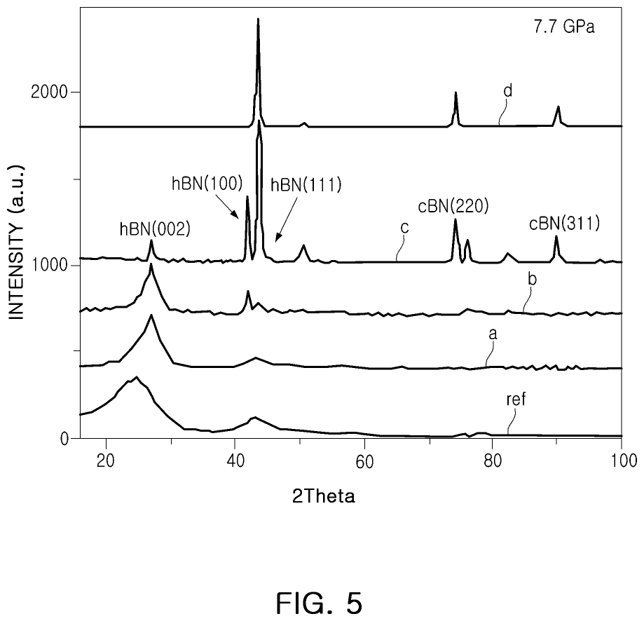

Referring to FIGS. 5, 6A-6D, and 7, in an example embodiment, the second insulating layer 130 may be implemented to have an optimal crystallization state based on physical properties of the silicon substrate W settled on the top.

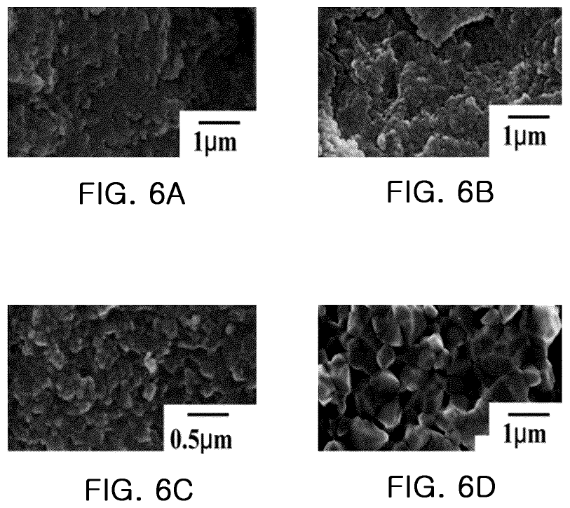

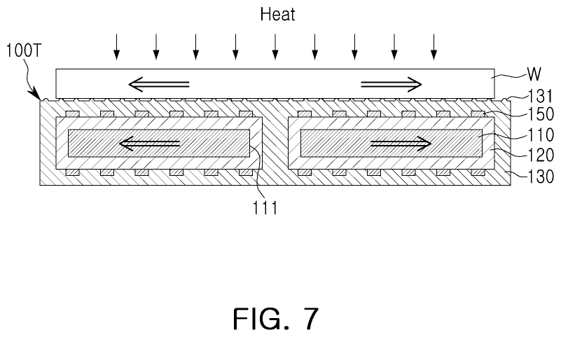

FIGS. 5 and 6A-6D illustrate graphs and SEM images respectively illustrating crystallization according to the temperature in pyrolytic boron nitride (pBN) forming an outermost surface of the substrate holding unit 100, and FIG. 7 illustrates an expansion direction of a substrate and a substrate holding unit according to crystallization.

In FIG. 5, graph ref. shows a crystal structure of an upper surface 100T of a second insulating layer 130 during a heat treatment at a low temperature, for example, 1500° C., graph a shows a crystal structure of an upper surface 100T of a second insulating layer 130 during a heat treatment at 1700° C., graph b shows a crystal structure of an upper surface 100T of a second insulating layer 130 during a heat treatment at 2000° C., graph c shows a crystal structure during a heat treatment at 2200° C., graph d shows a crystal structure during a heat treatment at 2400° C., and FIGS. 6A-6D show SEM images of the second insulating layer 130 with respect to a to d graphs, respectively.

Referring to FIGS. 5 and 6A-6D, respectively, when the second insulating layer 130, i.e., pyrolytic boron nitride (pBN), is formed by chemical vapor deposition and is then subject to an XRD analysis during a heat treatment at 1500° C., which is a relatively low temperature, as illustrated in graph ref., only a hexagonal crystal structure may be observed on the upper surface 100T. The heat treatment may be performed at high pressure and a high temperature. Graph a shows that the heat treatment is performed at a high temperature of about 1700° C. at a high pressure of 1 to 7.7 Gpa. It may be seen that during the heat treatment at 1700° C., a hexagonal crystal structure may be mainly generated, but a cubic crystal structure is partially generated. The cubic crystal structure may be partially confirmed in the SEM photo of FIG. 6A. Graph b shows that the heat treatment is performed at a high pressure of 1 to 7.7 Gpa at a high temperature of about 2000° C. It may be seen that during the heat treatment at 2000° C., the hexagonal crystal structure is mainly generated, but the cubic crystal structure is partially generated. The cubic crystal structure may be confirmed in the SEM image of FIG. 6B. Additionally, graph c shows that the heat treatment is performed at a high temperature of about 2200° C. and high pressure of 1 to 7.7 Gpa. It may be seen that during the heat treatment at 2200° C., a significant portion of the cubic crystal structure is generated. The cubic crystal structure may be confirmed in the SEM image of FIG. 6C. Additionally, graph d shows that the heat treatment is performed at a high temperature of about 2400° C. and high pressure of 1 to 7.7 Gpa. During the heat treatment at 2400° C., it may be seen that most of the cubic crystal structures are generated on the surface. Such the cubic crystal structure may be confirmed in the SEM image of FIG. 6D. An area of the crystal structure of the second insulating layer 130 in which the crystallization process has been performed by heat treatment at various temperatures is shown in Table 1.

TABLE 1

| | Crystal Structure Ratio | | | | | | | |
|---|---|---|---|---|---|---|---|---|
| Heat | | | | | Hexagonal | | Crystallization | |
| treatment | | | | | Structure/ | | | Area |
| temperature | | | | | Cubic | Percentage | Total area | percentage |
| (° C.) | Crystal Peak Area (mm²) | | | Sum | structure | (%) | (mm²) | (%) |
| 2200 | Hexagonal | (002) | 81.9 | 287.9 | 2.71 | 27% | 1788.6 | 59.8 |
| | Structure | (100) | 206.0 | | | | | |
| | Cubic | (111) | 526.9 | 782.5 | | 73% | | |
| | structure | (220) | 172.7 | | | | | |
| | | (311) | 82.9 | | | | | |
| 2000 | Hexagonal | (002) | 735.7 | 829.6 | 0.11 | 90% | 2096.5 | 46.6 |
| | Structure | (100) | 93.9 | | | | | |
| | Cubic | (111) | 94.9 | 94.9 | | 10% | | |
| | structure | | | | | | | |
| 1500 | Hexagonal | (002) | 1434 | 1434 | — | 100% | 1434 | 44.9 |
| | Structure | | | | | | | |

Table 1 shows crystallinity calculated using XRD analysis at 1500° C. as graph ref., 2000° C. as graph b, and 2200° C. as graph c in FIG. 5. Referring to Table 1, during the crystallization process at a relatively low temperature as shown in graph ref., it may be seen that crystallization occurs in an area of about 44.9% with respect to the total area of the upper surface, most of which has a hexagonal crystal structure. In this case, when the heat treatment temperature of the crystallization process is increased to 1700° C. or higher, for example, 2000° C. or 2200° C., a cubic crystal structure may be generated. The cubic crystal structure generated by the high-temperature heat treatment is generated more as the temperature increases, and an entire crystal structure generated at 2400° C. or higher may be changed to the cubic crystal structure.

In an example embodiment of the present disclosure, a heat treatment is performed at a temperature of 1700° C. or higher and less than 2400° C., pyrolytic boron nitride (pBN) including a mixed crystal structure in which a portion of the crystal structure includes a hexagonal crystal structure as the first crystal structure 130a and the rest includes a cubic crystal structure as the second crystal structure 130b may be applied to the second insulating layer 130.

On the second insulating layer 130, the crystallized area may satisfy 40% or more of the total area, and the cubic crystal structure as the second crystal structure 130b may satisfy 5% or more of the crystallized area. In some embodiments, the cubic crystal structure as the second crystal structure 130b may satisfy 10% or more and 73% or less of the crystallized area. In still further embodiments, the cubic crystal structure as the second crystal structure 130b may satisfy 10% or more and 50% or less of the crystallized area. The cubic crystal structure may have an area ratio of 0.1 to 2.7 times with respect to the hexagonal crystal structure, for example, an area ratio of 0.1 times to 1 times, more specifically, 0.1 times to 0.2 times, but the present disclosure is not limited thereto.

Accordingly, the second insulating layer 130 may include a crystallized area of 40% or more with respect to the total area, and an area occupied by the cubic crystal structure as the second crystal structure 130b may satisfy ½ or less of the crystallized area. As described above, when the second insulating layer 130 has a cubic crystal structure in ½ or less of the crystallized area while maintaining crystallization of 40% or more with respect to the total area of the upper surface 100T facing the substrate W, the second insulating layer 130 may have larger stiffness and a larger thermal expansion coefficient (CTE) as a surface area occupied by the cubic crystal structure increases.

As described above, when the cubic crystal structure is 10% or more of the crystallized area, the crystallized area may have a larger thermal expansion coefficient than when the crystallized area is formed as the entire hexagonal crystal, and may have a positive (+) thermal expansion coefficient. As illustrated in FIG. 7, when the substrate W disposed on the upper surface is a silicon substrate, since the thermal expansion coefficient CTE of silicon has a positive (+) thermal expansion coefficient CTE of (+)2.6 (10⁻⁶/K), force is applied to the outside by tension during the heat treatment. In this case, a surface of the second insulating layer 130 also exerts the force externally due to tension since the thermal expansion coefficient CTE is changed to have a positive (+) value by a partial cubic crystal structure of the second insulating layer 130. Accordingly, force may be applied in the same direction between two layers—e.g., the substrate W and the second insulating layer 130—in contact with each other, thereby minimizing an occurrence of particles in the second insulating layer 130.

Furthermore, since the second insulating layer 130 includes the cubic crystal structure by ½ or less of the total crystallized area to increase stiffness, but such stiffness may be set to have a value less than 12.5 Gpa, which is stiffness of the silicon substrate.

Therefore, since the cubic crystal structure is included in less than ½ of the cubic crystal structure, the stiffness does not exceed the stiffness of the silicon substrate W, and the problem of scratches on the silicon substrate W may be solved.

Accordingly, as the cubic crystal structure on the upper surface of the second insulating layer 130 includes ½ or less of the total crystallized area, the stiffness may be set to satisfy 0.2 to 12.5 Gpa, or more specifically 5 to 10 Gpa.

In this manner, by adjusting the heat treatment temperature of the crystallization process and an area for each crystal structure, it may be possible to provide a substrate holding unit 100 having a second insulating layer 130 satisfying desired stiffness and a desired thermal expansion coefficient (CTE).

Protruding patterns 131 may be settled on the surface of the second insulating layer 130. The protruding patterns 131 may have a uniform size and may be irregularly disposed, and a space spaced apart from the substrate W disposed on the top may be formed to form a passage of heat and source gas. The protruding patterns 131 may be limitedly disposed only on the upper surface 100T of the second insulating layer 130, and may not be disposed on the lower surface 100B.

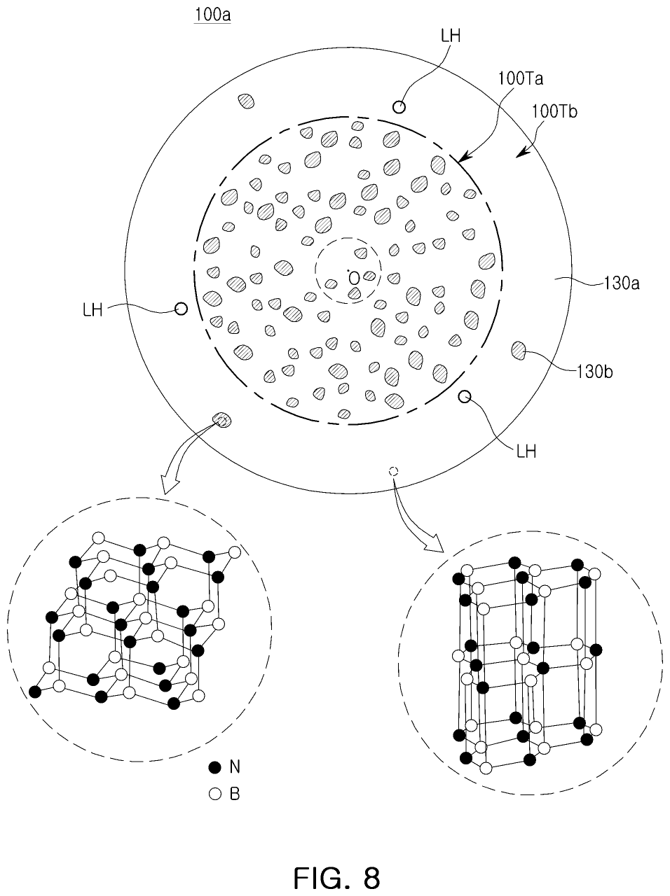

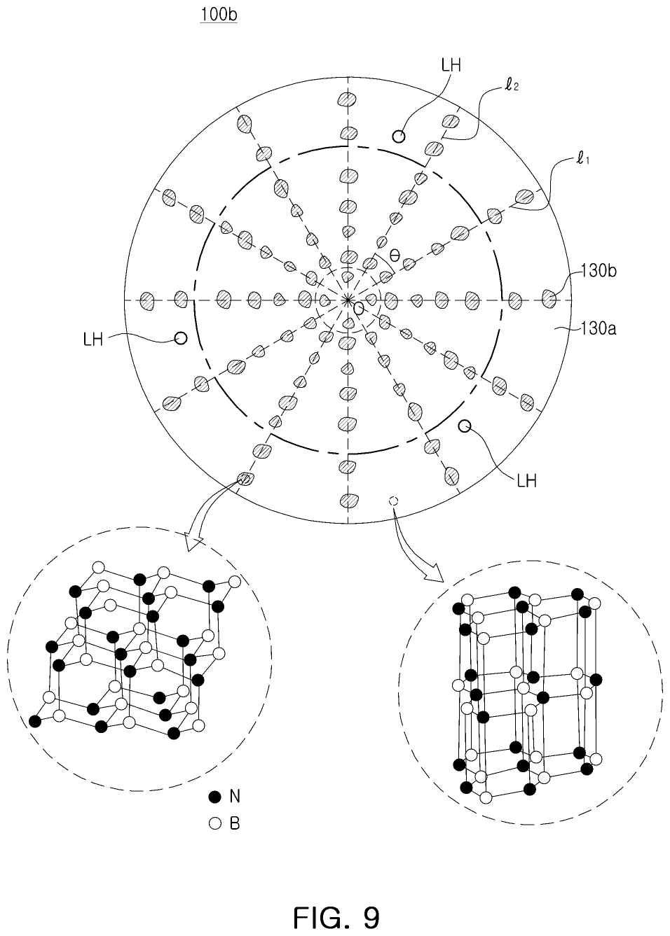

Hereinafter, a substrate holding unit according to various example embodiments of the present disclosure will be described with reference to FIGS. 8 and 9.

A substrate holding unit 100a of FIG. 8 may be the same as that of FIG. 4, except for a distribution of a second crystal structure 130b on an upper surface 100T of a second insulating layer 130.

In a substrate holding unit 100a of FIG. 8, a loading region 100Ta in which a substrate W is disposed on the upper surface 100T may be defined, and the loading region 100Ta may be defined as an internal region having a predetermined width in a center O of a circular shape when the upper surface 100T of the substrate holding unit 100a forms the circular shape. As illustrated in FIG. 8, when the loading region 100Ta is circular, a shape thereof is a circular shape having a predetermined diameter and may be concentric with the substrate holding unit 100a. However, the loading region 100Ta may be divided into a square or a polygon, and even when divided into a square, the loading region 100Ta may be divided to have the center O of the circular shape of the substrate holding unit 100a as an inner core.

In the second insulating layer 130, a region of the second crystal structure 130b on the upper surface 100T may be intensively disposed in the loading region 100Ta. For example, the second crystal structure 130b regions on the upper surface 100T may be disposed more densely in the loading region 100Ta. As illustrated in FIG. 8, density of the second crystal structure 130b in the loading region 100Tb and density of the second crystal structure 130b outside the loading region 100Tb are different from each other, and the density of the second crystal structure 130b in the loading region 100Ta may be greater than the density of the second crystal structure 130b outside the loading region 100Tb. The density of the second crystal structure 130b in the loading region 100Ta may be at least ten times the density of the second crystal structure 130b outside the loading region 100Tb, and since most of the second crystal structure 130b is dispersed in the loading region 100Ta, larger stiffness and a positive thermal expansion coefficient (CTE) may be achieved in a region in contact with the substrate W. Specifically, when the stiffness and the thermal expansion coefficient (CTE) of the loading region 100Ta are extended to be in a range similar to the stiffness and the thermal expansion coefficient (CTE) of the silicon substrate W, since both surfaces of the silicon substrate W and the second insulating layer 130 are protected, a lifespan may be increased, and a surface scratch of the substrate W may also be prevented. In FIG. 8, the density of the second crystal structure 130b is illustrated as changing rapidly using the loading region 100Ta as a boundary, but unlike this, the second crystal structure 130b may be arranged such that the density thereof gradually decreases from the center O of the substrate holding unit 100a toward a circumferential direction. A gradient of the second crystal structure 130b enables crystallization of a local region by performing a crystallization process by laser. As described above, even when the density of the second crystal structure 130b is different according to the region, the second crystal structure 130b may be disposed to occupy an area of 10% or more and 50% or less of the crystallized region, which is in a range of Table 1 with respect to the entire upper surface of the substrate holding unit 100a.

A substrate holding unit 100b of FIG. 9 may be the same as that of FIG. 4 except for the distribution of the second crystal structure 130b on an upper surface of the second insulating layer 130.

When an upper surface of the substrate holding unit 100b forms a circular shape, the second crystal structure 130b may be disposed in a radial direction from a center O of the circular shape.

In the second insulating layer 130, a region of the second crystal structure 130b on an upper surface thereof may be disposed in a radial direction from the center O of the circular shape, and may be disposed along a plurality of radiation lines (11, 12, . . . ).

The plurality of radial lines (11, 12, . . . ) are regions for dividing the upper surface 100T into a plurality of fan-shaped regions, as illustrated in FIG. 9, and may be divided at the same angle. For example, each of the fan-shaped regions may be of the same size. The second crystal structure 130b may be intensively disposed on each of the radial lines (11, 12, . . . ). As illustrated in FIG. 9, density of the second crystal structure 130b on the radial lines (11, 12, . . . ) and density of the other second crystal structures 130b are different from each other, and the density of the second crystal structure 130b on the radial lines (11, 12, . . . ) may be greater than the density of the other second crystal structures 130b. The density of the second crystal structure 130b on the radial lines (11, 12, . . . ) may satisfy at least 10 times the density of other second crystal structures 130b, and by distributing most of the second crystal structures 130b on the radial lines (11, 12, . . . ), the second crystal structure 130b may be concentrated in a specific region to prevent cracks from occurring because the thermal expansion coefficient (CTE) between a partial region and another region are different from each other on the upper surface 100T of the substrate holding unit 100b.

In FIG. 9, the density of the second crystal structure 130b is illustrated as changing rapidly using radial lines (11, 12, . . . ) as boundaries, but unlike this, the second crystal structure 130b may be arranged such that the density thereof gradually decreases toward adjacent radial lines (11, 12, . . . ) around each radial line (11, 12, . . . ). A gradient of the second crystal structure 130b enables crystallization of a local region by performing a crystallization process by laser. As described above, even when the density of the second crystal structure 130b is different according to the region, the second crystal structure 130b may be disposed to occupy an area of 10% or more and 50% or less of the crystallized region, which is in a range of Table 1 with respect to the entire upper surface 100T of the substrate holding unit 100b.

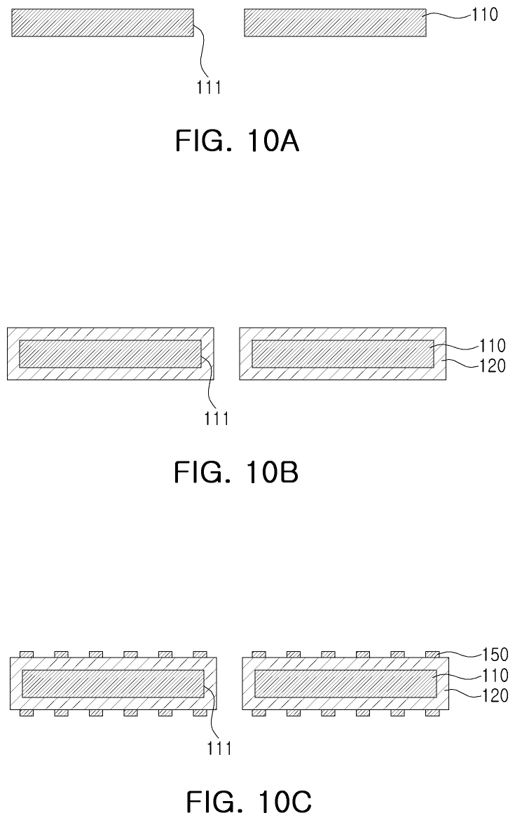

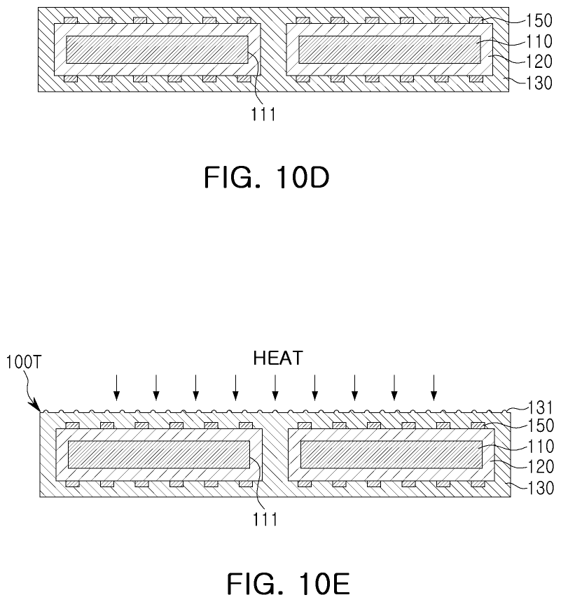

Hereinafter, a process for manufacturing the substrate holding unit 100 of FIG. 3 will be described with reference to FIGS. 10A to 10E.

First, referring to FIG. 10A, a core body 110 may be molded. The core body 110 may be initially processed using carbon or graphite among carbon composite materials as a base material, and the surface may be processed to be smoothened, and an opening hole 111 may be formed in a central region the core body 110 to have an overall shape. Impurity elements may be removed from the molded core body 110 through ultrasonic cleaning and drying. Ultrasonic cleaning may be performed within 3 minutes, and then drying may be performed at 105° C. or higher for 1 hour or more.

Referring to FIG. 10B, a first insulating layer 120 may be disposed on the core body 110. The first insulating layer 120 may be disposed so that pyrolytic boron nitride, whose thermal expansion ratio is similar to that of the core body 110, is deposited on an entire core body 110 through chemical vapor deposition (CVD).

A boron (B)-related precursor may be coated on the entire core body 110 by applying the CVD method at high temperatures, and a deposition thickness thereof may satisfy about 100 to 300 μm. In this case, since a mismatch between lattice constants of graphite and pyrolytic boron nitride (pBN) is very low, e.g., about 1 to 3%, stable crystal growth may be achieved. The first insulating layer 120 may be formed by deposition of pyrolytic boron nitride (pBN), and the first insulating layer 120 may be formed to cover the core body 110 up to an interior of the opening hole 111. Impurity elements may be removed through ultrasonic cleaning and drying. The ultrasonic cleaning may be performed in 3 minutes, and then drying may be performed at 105° C. or higher for 1 hour or more.

Referring to FIG. 10C, an electrode layer 150 including upper electrodes 150a and lower electrodes 150b may be formed on an upper surface and a lower surface of a first insulating layer 120, respectively.

First, the electrode layer 150 may be deposited entirely on the upper surface and the lower surface of the first insulating layer 120. The electrode layer 150 may be deposited using chemical vapor deposition (CVD) so that pyrolytic graphite (PG) has a thickness of approximately 50 μm. Next, the electrode layer 150 may be patterned to have an upper electrode 150a on an upper surface thereof and to have a lower electrode 150b on a lower surface thereof. When the patterning is completed, it is necessary to inspect whether pyrolytic graphite deposited by the chemical vapor deposition (CVD) may operate properly as an electrode, and it may be possible to change dimensions and electrical resistance of a coated electrode depending on desired resistance. After inspection, impurity element may be removed again through ultrasonic cleaning and drying. The ultrasonic cleaning may be performed in 3 minutes, and then the drying may be performed at 105° C. or higher for 1 hour or more.

Referring to FIG. 10D, a second insulating layer 130 may be formed to cover the upper electrode 150a and the lower electrode 150b. The second insulating layer 130 may be formed of the same pyrolytic boron nitride (pBN) as the first insulating layer 120, and pyrolytic boron nitride (pBN) may be deposited to cover the first insulating layer 120 and the upper and lower electrode layers 150 as a whole, using a chemical vapor deposition method, so as to have a thickness of 100 μm to 300 μm from the electrode layer 150. In this case, pyrolytic boron nitride (pBN) may be deposited to completely fill an opening hole 111 and flatten an upper surface of the second insulating layer 130. Impurity elements may be removed again through ultrasonic cleaning and drying. The ultrasonic cleaning may be performed in 3 minutes, and then the drying may be performed at 105° C. or higher for 1 hour or less.

Referring to FIG. 10E, a protruding pattern 131 may be formed on an upper surface of the second insulating layer 130. The protruding pattern 131 may be limitedly embossed only to a portion of a surface of the second insulating layer 130, specifically an upper surface thereof, and a height and a diameter of embossing may vary, depending on an overall diameter. An embossing treatment may be performed through wet etching, etc., but the present disclosure is not limited thereto. Next, a crystallization process may be performed on the surface of the second insulating layer 130. The crystallization process may be performed by injecting energy of a certain amount or more, and in FIG. 10E, the crystallization process may be advanced by performing annealing at high temperature and pressure. This heat treatment may be performed at a high temperature of about 1700° C. or higher and less than 2400° C. at high pressure of 1 to 7.7 Gpa, and a crystal structure may be changed to include a cubic crystal structure along with a hexagonal crystal structure. Accordingly, the cubic crystal structure can be formed in 10 to 73% of the total crystallized area in FIG. 3. In some embodiments, the cubic crystal structure may form 10 to 50% of the total crystallized area.

In this manner, by performing the heat treatment on the surface of the second insulating layer 130 of pyrolytic boron nitride (pBN) to have a partial cubic crystal structure, stiffness of the second insulating layer 130 may be increased and the crystal structure may be changed so that the thermal expansion coefficient (CTE) has a positive (+) value. Accordingly, an occurrence of particles during the heat treatment of the substrate W disposed on the upper surface 100T may be significantly reduced, and scratches may be prevented from occurring on the substrate W.

The substrate processing apparatus 200 employed in this example embodiment may be a PECVD apparatus, as described above. For example, referring to FIG. 1, a shower head 240 may also function as an upper electrode of a parallel plate electrode.

By disposing a lower electrode (ground electrode) (not illustrated) in the second insulating layer 130 of the substrate holding unit 100 and supplying high frequency power to the shower head 240, a high-frequency electric field may be formed between the shower head 240 and the lower electrode, and process gas supplied from the shower head 240 may be converted into plasma by the high-frequency electric field. Although not illustrated, the process chamber 210 may further include a plasma generation unit (not illustrated) generating plasma from the process gas. For example, the plasma generation unit (not shown) may have a capacitively coupled plasma source or an inductively coupled plasma source.

In the above-described example embodiment, the substrate processing apparatus is exemplified as the PECVD apparatus, but the substrate holding unit 100 according to an example embodiment of the present disclosure may be advantageously employed in other types of substrate processing apparatuses for heating a substrate (e.g., a semiconductor wafer) at high temperatures. For example, in addition to the PECVD apparatus, the substrate processing apparatus may also be implemented as a deposition apparatus such as another CVD apparatus or sputtering apparatus, and an etching apparatus such as a plasma etching apparatus.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A substrate holding unit, comprising:
a core body having a first surface configured to support a substrate and a second surface opposite to the first surface;
an electrode layer disposed on the first surface and the second surface of the core body; and
a ceramic insulating layer covering the electrode layer and disposed on the first surface and the second surface of the core body,
wherein a first surface of the ceramic insulating layer on the first surface of the core body includes a cubic crystal structure in at least a portion thereof, and includes a hexagonal crystal structure in at least another portion thereof.

2. The substrate holding unit of claim 1, wherein the electrode layer comprises:
an upper electrode layer disposed on the first surface of the core body to provide electrostatic force to the substrate; and
a lower electrode layer disposed on the second surface of the core body to provide heat to the substrate as a heating resistor.

3. The substrate holding unit of claim 1, wherein the ceramic insulating layer includes pyrolytic boron nitride.

4. The substrate holding unit of claim 3, wherein on the first surface of the ceramic insulating layer, the cubic crystal structure is disposed in an area of 50% or less of a crystallized region.

5. The substrate holding unit of claim 3, wherein on the first surface of the ceramic insulating layer, the cubic crystal structure is disposed in an area of 10% to 50% of a crystallized region.

6. The substrate holding unit of claim 5, wherein on the first surface of the ceramic insulating layer, the crystallized region is 40% or more of a total area.

7. The substrate holding unit of claim 1, wherein a region having the cubic crystal structure of the ceramic insulating layer is irregularly dispersed.

8. The substrate holding unit of claim 1, wherein on the first surface of the ceramic insulating layer, a density of the cubic crystal structure in a region on which the substrate is placed is greater than a density of the cubic crystal structure in a region on which the substrate is not placed.

9. The substrate holding unit of claim 8, wherein the cubic crystal structure is concentrated in a central region of the first surface of the ceramic insulating layer.

10. The substrate holding unit of claim 1,
wherein the ceramic insulating layer comprises:
a first insulating layer disposed on the core body to cover the core body; and
a second insulating layer disposed on the electrode layer and the first insulating layer, and
wherein the cubic crystal structure is included in the second insulating layer of the first surface of the ceramic insulating layer.

11. The substrate holding unit of claim 10, wherein the first insulating layer and the second insulating layer include the same material.

12. The substrate holding unit of claim 3, wherein a thermal expansion coefficient of the pyrolytic boron nitride of the ceramic insulating layer has the same sign as a thermal expansion coefficient of the substrate, and a stiffness of the ceramic insulating layer is less than a stiffness of the substrate.

13. A substrate holding unit, comprising:
a core body having a first surface configured to support a substrate and a second surface opposite to the first surface;
an electrode layer disposed on the core body and including pyrolytic graphite providing heat to the substrate; and
a ceramic insulating layer covering the electrode layer and disposed on the first surface and the second surface of the core body, and including pyrolytic boron nitride,
wherein a first surface of the ceramic insulating layer on the first surface of the core body includes a cubic crystal structure in at least a portion thereof, and includes a hexagonal crystal structure in at least another portion thereof, and an area of the cubic crystal structure is 0.1 to 0.2 times an area of the hexagonal crystal structure.

14. The substrate holding unit of claim 13, wherein a thermal expansion coefficient of the pyrolytic boron nitride of the ceramic insulating layer has the same sign as a thermal expansion coefficient of the substrate, and a stiffness of the ceramic insulating layer is less than a stiffness of the substrate.

15. The substrate holding unit of claim 13, wherein the first surface of the ceramic insulating layer has a positive thermal expansion coefficient and has a stiffness of 0.2 to 12.5 Gpa.

16. The substrate holding unit of claim 14, wherein the ceramic insulating layer includes a crystallized region of 40% or more of the first surface, and includes the cubic crystal structure of 10% to 50% in the crystallized region.

17. The substrate holding unit of claim 13, wherein the ceramic insulating layer includes a plurality of protruding structures spaced apart from each other on the first surface.

18. The substrate holding unit of claim 13, wherein the electrode layer comprises:
an upper electrode layer disposed on the first surface of the core body to provide electrostatic force to the substrate; and
a lower electrode layer disposed on the second surface of the core body to provide heat to the substrate as a heating resistor.

19. A substrate processing apparatus, comprising:
a process chamber providing an internal space for processing a substrate;
a support unit disposed in the internal space and configured to support the substrate; and
a gas supply unit supplying process gas to the internal space,
wherein the support unit comprises:
a core body having a first surface for supporting the substrate and a second surface opposite to the first surface;
an electrode layer disposed on the first surface and the second surface of the core body; and
a ceramic insulating layer covering the electrode layer and disposed on the first surface and the second surface of the core body,
wherein a first surface of the ceramic insulating layer on the first surface of the core body includes a cubic crystal structure in at least a portion thereof, and includes a hexagonal crystal structure in at least another portion thereof.

20. The substrate processing apparatus of claim 19,
wherein the electrode layer includes pyrolytic graphite,
wherein the ceramic insulating layer includes pyrolytic boron nitride (pBN), and
wherein the ceramic insulating layer includes a crystallized region of 40% or more of the first surface, and includes the cubic crystal structure of 10% to 50% in the crystallized region.
